(19) United States
(12) Patent Application Publication
(10) Pub. No.: US 2008/0029888 A1
(43) Pub. Date: Feb. 7, 2008

(54) Solder Interconnect Joints For A Semiconductor Package

(75) Inventors: Seungbae Park, Vestal, NY (US); Sanjeev Sathe, Johnson City, NY (US); Aleksander Zubelewicz, Los Alamos, NM (US)

Correspondence Address: BOND SCHOENECK & KING, PLLC, ONE LINCOLN CENTER, SYRACUSE, NY, 13202, US

(73) Assignee: International Business Machines Corporation, Armonk, NY (US)

(21) Appl. No.: 11/610,793

(22) Filed: Dec. 14, 2006

Related U.S. Application Data
(63) Continuation-in-part of application No. 10/038,264, filed on Jan. 3, 2002, now abandoned.
Application No. 10/038,264 is a division of application No. 09/430,965, filed on Nov. 1, 1999, now Pat. No. 6,347,901.

(51) Int. Cl. H01L 23/488

(52) U.S. Cl. 257/737; 257/E23.023

(57) ABSTRACT

A method and article of fabrication is described featuring a solder layer having a serpentine, interrupted, or interdigitated boundary. The non-planar design of the boundary layer increases the fatigue life of the solder joint by limiting the damage caused by micro-cracking. This irregularity of the solder boundary constrains the propagation of cracks by creating obstacles along the crack path, redirecting the crack away from the intermetallic layer, or by increasing the path along which the crack propagates.

### CROSS-REFERENCE TO RELATED APPLICATIONS

This application is a continuation-in-part of U.S. patent application Ser. No. 10/038,264, filed Jan. 3, 2002, which is a divisional of U.S. patent application Ser. No. 09/430,965, filed Nov. 1, 1999.

### BACKGROUND OF THE INVENTION

1. Field of the Invention

The present invention relates to soldering techniques and, more particularly, to a solder method that enhances solder interconnects by eliminating solder joint failures in semiconductor packages that are caused by micro-cracking at or near the solder intermetallic interface between the semiconductor pad and substrate pad.

2. Description of the Related Art

The fatigue life of solder interconnects is often poor, because cracks develop near an intermetallic layer. The damaging process is due to the build-up of inelastic deformation (creep) that leads to cavity nucleation, growth, and coalescence along grain boundaries. The increasing damage tends to produce micro-cracks at the boundaries. These boundary micro-cracks are disposed roughly normal to the direction of maximum tensile stress.

The factors that influence the aforementioned damage include: (a) the shape of the joint, which influences the stress concentration at the free joint boundaries; (b) the build-up of intermetallics, which are known to locally increase stress in solder at and above the intermetallic layer; and (c) the local coefficient of thermal expansion (CTE) mismatch between the pad and the solder.

It is also observed that dissolved copper, gold, or other metallic pad coating materials locally contaminate solder. The contaminants increase the solder brittleness, making the solder susceptible to micro-cracking, when compared with bulk behavior.

In U.S. Pat. No. 5,242,569, issued to Kang et al, on Sep. 7, 1993, for THERMOCOMPRESSION BONDING IN INTEGRATED CIRCUIT PACKAGING, a thermocompression bonding method is described that allows bonding to be achieved at lower temperatures. The process produces a soft, deformable layer of metal that is free of dendritic protrusions.

In U.S. Pat. No. 5,172,473, issued to Burns et al, on Dec. 22, 1992, for METHOD OF MAKING CONE ELECTRICAL CONTACT, a method of achieving improved electrical contact is illustrated. Contact is improved by generating cone-shaped projections upon a mating surface. The cones enhance ohmic contact by intermeshing and wiping.

In U.S. Pat. No. 5,118,299, issued to Burns et al, on Jun. 2, 1992, for CONE ELECTRICAL CONTACT, an electrical interconnection is shown featuring two detachable surfaces having intermeshing cone projections. The cones enhance ohmic contact by intermeshing and wiping.

In U.S. Pat. No. 3,881,799, issued on May 6, 1975, to Elliott et al, for RESILIENT MULTI-MICRO POINT METALLIC JUNCTION, a dynamic interfacing contact device is disclosed. The device provides multiple points of contact between opposing parallel surfaces of a pair of conductors. The points of contact are provided by a number of spaced-apart, metal protrusions.

In U.S. Pat. No. 4,751,563, issued to the common assignee, a microminiaturized electrical interconnection device is described. Electrical connection on a first pad is tangentially raised at about sixty degrees and brought into intimate contact with a second metallic layer.

### BRIEF SUMMARY OF THE INVENTION

It is therefore a principal object and advantage of the present invention to provide a method and article of fabrication that improves the fatigue life of solder joints.

It is another object of the invention to produce a solder joint that constrains cracking along the intermetallic boundary.

In accordance with the present invention, there is provided a method and article of fabrication, featuring a solder layer that comprises a serpentine, interrupted, or interdigitated boundary. The non-planar design of the boundary layer increases the fatigue life of the solder joint, by limiting the damage caused by micro-cracking. This irregularity of the solder boundary constrains the propagation of cracks by creating obstacles along the crack path, redirecting the crack away from the intermetallic layer, or by increasing the path length along which the crack propagates. The present invention seeks to increase the fatigue life of the solder joint, by limiting the damage caused by micro-cracking in the solder joint. This objective is achieved by redistributing the stresses in solder, thus constraining the cracks. Such containment can be accomplished by creating obstacles along the crack path, redirecting the crack away from the intermetallic layer, or by increasing the path length along which the crack is to propagate. The solder layer can be designed to include a serpentine, interrupted, or interdigitated boundary. The method can be applied to ball grid arrays, column grid arrays, surface mount technology (SMT) joints, etc.

### BRIEF DESCRIPTION OF THE DRAWINGS

A complete understanding of the present invention may be obtained by reference to the accompanying drawings, when considered in conjunction with the subsequent detailed description, in which:

FIG. 1 illustrates a side view of the edge of the solder boundary of a prior art metallic pad;

FIG. 2 depicts a plan view of the micro-crack propagation at the solder boundary layer, using the solder configuration of FIG. 1;

FIG. 2a is a greatly enlarged photograph of actual solder pads with defects represented in FIG. 2;

FIGS. 3a through 3g show a plan view of seven embodiments of the pad configuration of this invention; and

FIG. 4 illustrates a plan view of the micro-crack propagation at the solder boundary layer, using the pad configuration of FIG. 3a.

### DETAILED DESCRIPTION OF THE INVENTION

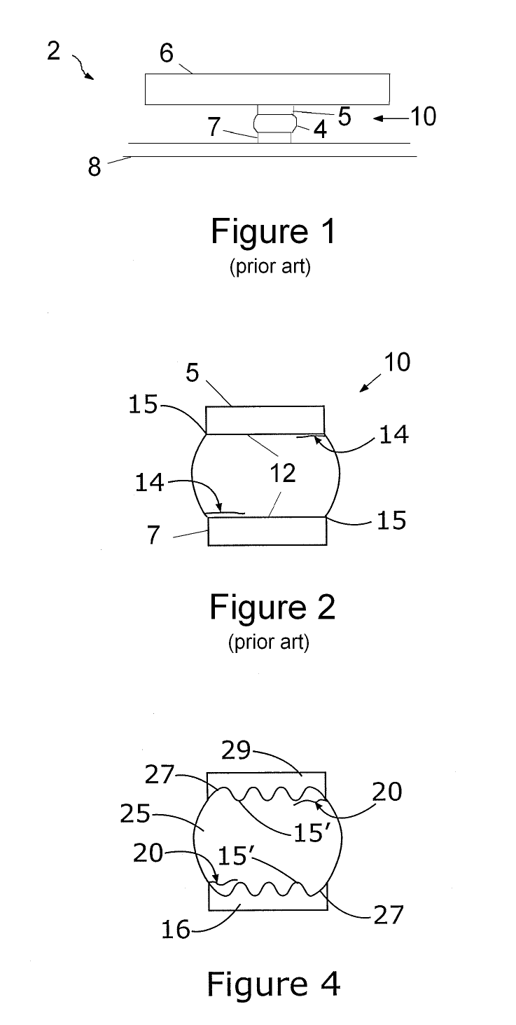

Referring now to the drawings, wherein like reference numerals refer to like parts throughout, there is seen in FIG. 1 a conventional electronic package 2 including a solder joint 10 interconnecting a semiconductor 6, such as an integrated chip, to a substrate 8, such as a printed circuit board. Solder joint 10 generally comprises a solder ball 4 interconnected to a metal pad 5 of semiconductor 6 and also interconnected to a metal pad 7 of substrate 8, thereby electrically interconnecting semiconductor 6 to substrate 8. It should be recognized by those of ordinary skill in the art that the present invention is directed to applications such as ball grid arrays, column grid arrays, and surface mount technology (SMT), all of which are well known forms of geometry used for mounting semiconductor chips to substrates and forming semiconductor packages.

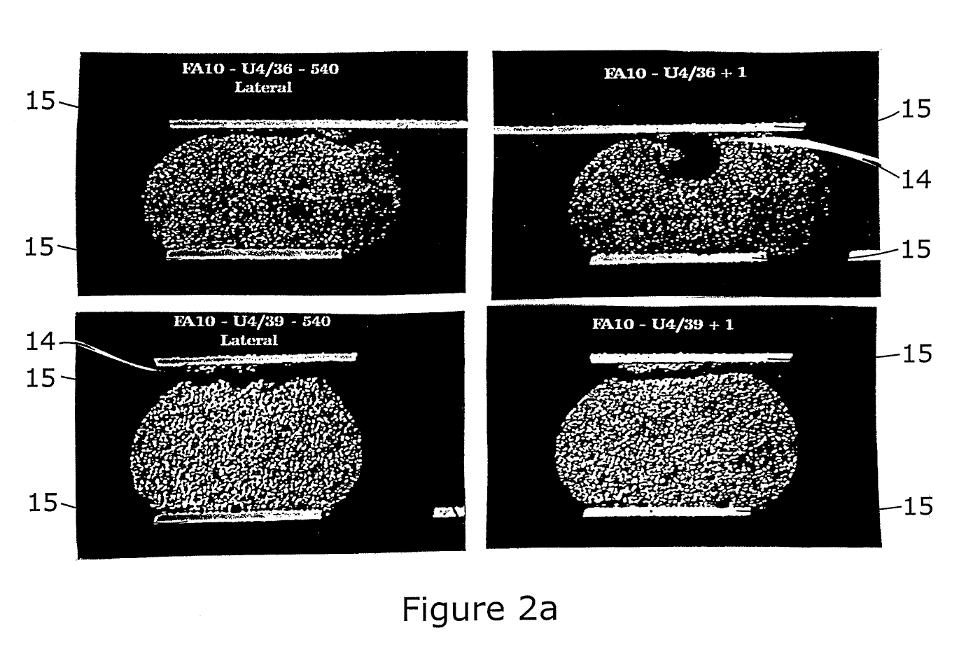

As seen in FIG. 2, in a conventional solder joint 10 micro-cracks 14 are free to propagate in solder joint 10 near the junction point 15 between solder ball 4 and each of pads 5 and 7. Micro-cracks 14 form in the interface or boundary layer adjacent to the junction point 15 of solder ball 4 and pads 5 and 7 because of the formation of intermetallic compounds, i.e., the chemical mixing of the elements in solder ball 4 with the elements of pads 5 and 7, near junction point 15. Micro-cracks 14 are then free to propagate in this region because there is no constraint against their growth.

Generally speaking, the present invention features a method as well as solder pad configurations which increase the fatigue life of solder joint 10 by preventing or reducing the formation of micro-cracks 14. The method and pad configurations of the present invention reduce the damage which is normally caused by micro-cracking at the solder and near intermetallic interface or boundary layer by constraining the propagation of cracks with obstacles placed along the crack path. In particular, the obstacles reduce propagation by redirecting the crack away from the intermetallic layer or by increasing the path along which the crack must propagate.

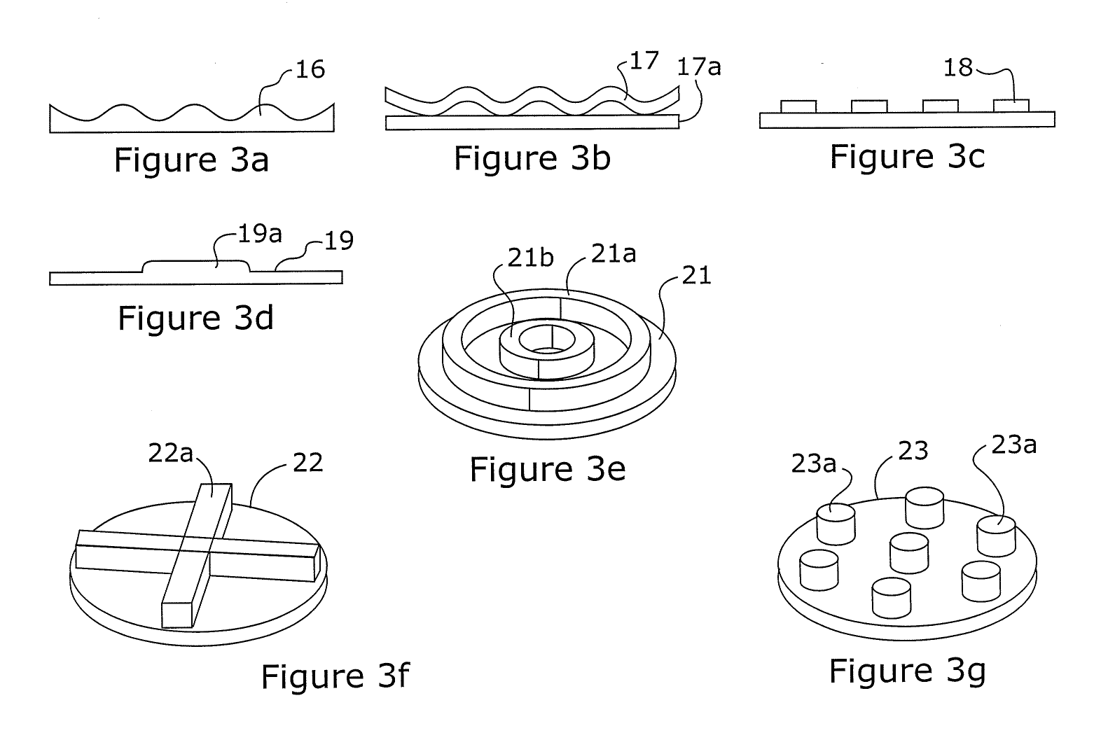

Referring to FIGS. 3a through 3g, a variety of irregularly shaped pads 16, 17, 18, 19, 21, 22, and 23 that may be used to control the propagation of micro-cracks are depicted. FIG. 3a depicts an undulating or serpentine pad 16. FIG. 3b shows an undulating or serpentine pad 17 further attached to a planar base pad 17a. FIG. 3c illustrates an interdigitated strip positioned on pad 18. FIG. 3d depicts a raised member 19a of pad 19 having a curved edge; FIG. 3e depicts a pad 19 having raised, concentric walled members 21a and 21b. FIG. 3f shows a pad 22 having a raised cross-shaped member 22a thereon. FIG. 3g illustrates a pad 23 having a plurality of foreshortened, substantially cylindrical members 23a disposed perpendicularly thereon with respect to the major plane of the pad 23.

Referring to FIG. 4, there is shown a cross-sectional view of a solder joint 10′ according to the present invention. More specifically, solder joint 10′ comprises a solder ball 25 interconnecting two pads 16 and 29, such as the pads of a substrate and semiconductor. Each of pads 16 and 29 has a substantially planar surface and an opposing surface including means for interrupting microcracks. For example, in the configuration of FIG. 4, pads 16 and 19 have the serpentine configuration depicted in FIG. 3a. As generally occurs during a soldering operation, junction point 15′ results in a layer of intermingled metallic compounds. Micro-cracks 20 forming at or near each junction point 15′ will follows a circuitous or meandering path as a result of the means for interrupting microcracks on the surfaces of pads 16 and 29. The lengthening of the crack pathway increases the useful life of the solder joint. Other pad configurations acceptable for providing means for interrupting microcracks are shown in FIGS. 3b through 3d. As is the case with the configuration of FIG. 3, these other configurations also result in micro-crack pathways which are interrupted, lengthened, or constrained. In similar manner, these configurations are expected to increase fatigue life of the solder joint, as is that of the solder design shown in FIG. 3a.

Since other modifications and changes varied to fit particular operating requirements and environments will be apparent to those skilled in the art, the invention is not considered limited to the examples chosen for the purpose of disclosure, and covers all changes and modifications which do not constitute departures from the true spirit and scope of this invention.

What is claimed is:

1. A semiconductor package comprising an electronic chip interconnected to a substrate, said package comprising:
a first metallic pad electrically and physically connected to said substrate and having a substantially planar first lower surface engaging said substrate and a first upper surface including a first plurality of serpentine undulations extending upwardly;
a second metallic pad electrically and physically connected to said chip and having a substantially planar second upper surface engaging said chip and a second lower surface including a second plurality of serpentine undulations extending downwardly; and
solder interconnecting said first upper surface with said second lower surface, whereby micro-cracks forming in said solder adjacent to said first upper surface or said second lower surface encounter said first plurality of serpentine undulations and said second plurality of serpentine undulations, respectively.

2. The package of claim 1, further comprising a first intermetallic boundary formed at the connection of said solder and said first upper surface, and a second intermetallic boundary formed at the connection of said solder and said second lower surface.

3. The package of claim 2, wherein said microcracks form in said first and second intermetallic boundaries.

4. The package of claim 3, wherein said microcracks forming in said first and second intermetallic boundaries are redirected by said first upper surface and said second lower surface.

5. The package of claim 4, wherein said microcracks forming in said first and second intermetallic boundaries are lengthened as a result of encountering said first upper surface and said second lower surface.

6. A semiconductor package comprising an electronic chip interconnected to a substrate, said package comprising:
a first metallic pad electrically and physically connected to said substrate and having a substantially planar first lower surface engaging said substrate and first means for interrupting microcracks extending upwardly from an upper surface;
a second metallic pad electrically and physically connected to said chip and having a substantially planar second upper surface engaging said chip and a second lower surface second means for interrupting microcracks extending downwardly from a lower surface; and
solder interconnecting said first upper surface with said second lower surface.

7. The package of claim 6, further comprising a first intermetallic boundary formed at the connection of said solder and said first upper surface, and a second intermetallic boundary formed at the connection of said solder and said second lower surface.

8. The package of claim 7, wherein said microcracks form in said first and second intermetallic boundaries.

9. The package of claim 8, wherein said microcracks forming in said first and second intermetallic boundaries are redirected by said first and second means for interrupting microcracks.

10. The package of claim 9, wherein said microcracks forming in said first and second intermetallic boundaries are lengthened as a result of encountering said first and second means for interrupting microcracks.

11. The package of claim 6, wherein said first means for interrupting microcracks comprises at least one structure selected from the group consisting of serpentine undulations in said pad, a raised strip having serpentine undulation on said pad, an interdigitated strip on said pad, a raised member on said pad having a curved edge, a concentric walled member on said pad, a cross-shaped member on said pad, and a plurality of cylindrical members on said pad.
